(19) United States
(12) Patent Application Publication
(10) Pub. No.: US 2014/0220496 A1
(43) Pub. Date: Aug. 7, 2014

(54) METHOD OF FORMING PHOTORESIST STRUCTURE

(71) Applicants: Hsien-Yeh Chen, Taipei (TW); Mu-Gi Wu, Taipei (TW); Chieh-Chen Hsieh, Taipei (TW); Hung-Lun Hsu, Taipei (TW); Kai-Wen Hsiao, Taipei (TW)

(72) Inventors: Hsien-Yeh Chen, Taipei (TW); Mu-Gi Wu, Taipei (TW); Chieh-Chen Hsieh, Taipei (TW); Hung-Lun Hsu, Taipei (TW); Kai-Wen Hsiao, Taipei (TW)

(73) Assignee: NATIONAL TAIWAN UNIVERSITY, Taipei (TW)

(21) Appl. No.: 14/023,069

(22) Filed: Sep. 10, 2013

(30) Foreign Application Priority Data
Feb. 6, 2013 (TW) 102104522

(51) Int. Cl. G03F 7/16

(52) U.S. Cl. CPC G03F 7/167
USPC 430/325

(57) ABSTRACT

A method for forming a photoresist structure is provided The method includes the step of forming a photoresist layer on a substrate, the step of exposing a portion of the photoresist layer to form an exposed portion of the photoresist layer, and the step of removing the photoresist layer except the exposed portion with a solvent, so as to form the photoresist structure, wherein the photoresist layer has a polymer having a structure represented by formula (I). The method of the present invention can generate a photoresist with an even thickness on devices with complex geometries or three-dimensional substrates. Thus, it can be applied to tissue engineering scaffolds, three-dimensional cell cultivation system and novel bio-microelectromechnical elements.

### BACKGROUND OF THE INVENTION

1. Field of the Invention

The present invention relates to methods of forming photoresist structures, and more particularly, to a method of forming a negative photoresist structure by using chemical vapor deposition.

2. Description of Related Art

Developing advanced biomaterials depends on the physical properties of the bulk material, such as mechanical strength, structural formula, and shape, as well as the surface chemistry that directly interacts with the biological systems. The latter has attracted considerable attention to become a unique research area known as biointerface sciences, and plays a crucial role in determining successful device fabrication for many biotechnological applications. The ability to control biomolecules at the solid/liquid interface requires adequate knowledge and understanding of surface interactions, transport phenomena of interacting molecules, interactions with external stimuli, and surface functional groups. Because chemically covalently linked biomolecules have endurance and stability, they can be effectively used in development of surface science. Moreover, the need to precisely incorporate biomolecules at specific locations at a micro/nanoscale (i.e., in confined micro/nanodomains) and to induce topographically derived responses in both in vivo and in vitro biological systems has become essential. These concepts have promoted modern schemes for designing complex biomaterials, and are rapidly guiding biointerface sciences into the realm of multifunctional biomimicry.

Recently, studies have explored the formation of micro/nanostructures with defined surface chemistry on various substrates, thus enabling the production of advanced biomaterials and devices and enhancing the understanding of the fundamentals of biology. Typically, such structures are fabricated by employing conventional photolithography using well-established knowledge and techniques. However, conventional techniques have several disadvantages as follows. (i) Conventional spin-coating techniques used during photolithography processing are intrinsically limited to flat two-dimensional (i.e., 2D) substrates. (ii) Using harmful substances (e.g., harsh solvents and/or intense irradiation) in the patterning and coating/developing processes is compatible with incorporating biomolecules during the fabrication process. (iii) Introducing multiple biomolecules on the structured surfaces is challenging because of the multiple steps required for the lithographic procedures, and proper selection of surface modification techniques is required for the substrates and resists.

To fulfill the growing demands in the fields of modern biology and biomaterials, it is imperative to develop novel photoresists for use in biotechnology to provide properties compatible with the biological environments, complementary patterning processes that avoid harmful substances in contact with sensitive biomolecules, the capability to accommodate multiple biomolecules simultaneously on the resulting microstructures, and accessibility of unhindered curves and complex substrate geometries.

### SUMMARY OF THE INVENTION

The present invention provides a method for forming a photoresist structure, including the following steps of: forming a photoresist layer above a substrate; exposing a portion of the area of the photoresist layer; and removing the photoresist layer except the exposed portion with a solvent, so as to form the photoresist structure, wherein the photoresist layer is comprised of a polymer having a structure represented by formula (I):

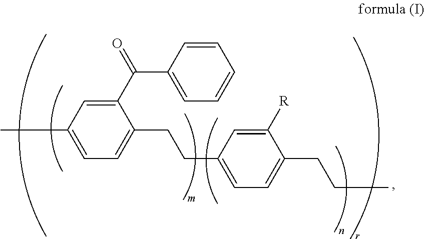

wherein R is benzoyl or a hydrogen atom; m and n are each independently an integer in a range from 1 to 150; and r is an integer in a range from 1 to 20000.

The polymer having the structure of formula (I) has a high biological and environmental compatibility, such that it can be formed on a structure with a complex geometry and a three-dimensional (3D) structure, and thereby enabling applications in tissue engineering scaffolds, three-dimensional cell cultivation systems, novel biological microelectromechanical devices, and the like. In the present invention, the polymer having the structure of formula (I) is formed on a substrate with a hindered curve and a complex geometry by a vapor deposition process, and the thickness of the obtained photoresist can be controlled to be tens of nanometers to provide the photoresist technology needed for biotechnical applications.

### BRIEF DESCRIPTION OF THE DRAWINGS

FIGS. 1(a) to 1(e) are schematic diagrams of IPRAS spectra, wherein FIG. 1(a) indicates a deposited photoresist layer by using a photoresist 1, FIG. 1(b) shows a photoresist layer after UV irradiation, FIG. 1(c) shows an UV-exposed photoresist layer after a development in acetone, FIG. 1(d) shows a first polymer layer 20 by depositing a polymer 2, FIG. 1(e) shows a layered photoresist layer 10 formed by the photoresist 1 and the polymer 2, and the first polymer layer 20, wherein the spectrum shows the characteristics and fingerprint bands from both the photoresist 1 and the polymer 2 relative to the reference spectra from FIGS. 1(a) and 1(d), and FIG. 1(f) shows that after development in acetone, only a band from the first polymer layer 20 is detected;

FIGS. 2(a) to 2(d) are schematic diagrams of the structural characterizations of the photoresist layer 10 after photolithography and a development, wherein FIG. 2(a) is an SEM image showing a uniform 50 μm×50 μm square array of the photoresist 1 over a 1.5 mm×1.5 mm area, FIG. 2(b) shows an imaging ellipsometry thickness map of a 50 μm×50 μm square array over a 400 μm×400 μm area, and FIGS. 2(c) and 2(d) show the data results of an QCM analysis performed on photoresist layers with average thicknesses of 2.5 μm and 496 μm, respectively;

FIG. 3(a) is a schematic diagram showing surface microstructures of the photoresist layer 10 formed by the photoresist 1, the polymer 2 and a polymer 3, the first polymer layer 20 and the second polymer layer 30;

FIG. 3(b) is a fluorescent micrograph of the second polymer layer 30;

FIG. 3(c) is a fluorescent micrograph of the first polymer layer 20;

FIG. 3(d) is a set of superimposed images of the parts of FIGS. 3(b) and 3(c);

FIG. 3(e) is an SEM image;

FIG. 3(f) is an imaging ellipsometry thickness map (bottom image) and a thickness profile (top image);

FIG. 4(a) is a schematic diagram of microscopic projection patterning on a stent substrate, wherein directed UV light is projected to a photoresist-coated stent through a designed photomask and a microscopic lens, the polymer 2 deposited on the stent to form the first polymer layer 20, the photoresist 1 deposited as an intermediate layer to form the photoresist layer 10, and a polymer 4 is deposited as a top layer to form a third polymer layer 40;

FIGS. 4(b) to 4(e) are fluorescent images, wherein FIG. 4(b) is an SEM micrograph showing a one-time projection applied to a conjunction area, FIG. 4(c) is an SEM micrograph showing two consecutive projections applied to a string area, FIGS. 4(d) and 4(e) are diagrams showing the detection of a green, immobilized FITC-streptavidin in an exposed area containing aldehyde groups, and the red Atto-655 NHS ester molecule only bounded to an amine-containing microstructure domain, respectively.

### DETAILED DESCRIPTION OF THE PREFERRED EMBODIMENTS

In an embodiment, the present invention provides a method for forming a photoresist structure, including the following steps of: forming a photoresist layer on a substrate; exposing a portion of the area of the photoresist layer to form an exposed portion of the photoresist layer; and removing the photoresist layer except the exposed portion by a solvent, so as to form the photoresist structure, wherein the photoresist layer has a polymer having a structure represented by formula (I):

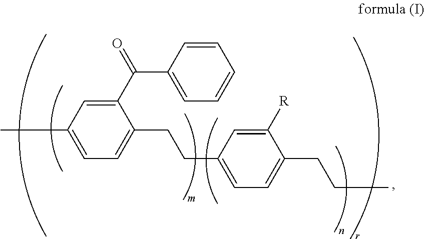

wherein R is benzoyl or a hydrogen atom; m and n are each independently an integer in a range from 1 to 150; and r is an integer in a range from 1 to 20000.

According to one embodiment, the formed photoresist layer has a polymer having a structure represented by formula (II):

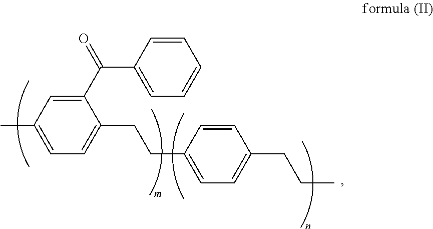

wherein m:n is 1:1.

Parylene family is a biocompatible photoreactive polymer, which can be deposited by polymerization using chemical vapor deposition (hereinafter, referred to as “CVD”) at a broad range. Based on the above, a parylene-functionalized polymer is formed on a substrate by chemical vapor deposition in the present invention.

Specifically, the present invention uses chemical vapor deposition process to deposit a parylene-functionalized polymer. For example, in an embodiment, chemical vapor deposition is used to form a photoresist layer having a polymer having a structure represented by formula (I), so as to be able to control the thickness of the produced photoresist layer to be tens of nanometers, and the thickness is even.

According to one embodiment, the thickness of the formed photoresist is in a range from 70 nm to 2.5 μm.

As compared with the conventional approach which coats a liquid-phase photoresist material on a substrate by using a spin-coating method, the present invention uses chemical vapor deposition to evenly deposit the photoresist layer on various substrates having complex geometries. Hence, as compared with the conventional spin-coating which is limited to flat two-dimensional components, the present invention uses a photoresist structure formed by chemical vapor deposition, without being limited to devices or substrates having surfaces with flat two-dimensional structures. The present invention can be extended to applications on devices or substrates having substrates with complex three-dimensional geometric structures, for example, tissue engineering scaffolds, three-dimensional cell cultivation systems and novel biological microelectromechanical devices.

In the present invention, when exposed to UV irradiation at about 365 nm, the solvent stability of the parylene-functionalized polymer in acetone is significantly increased. This is because a benzophenone side chain is crosslinked with an adjacent molecule. Thus, the present invention uses UV as an exposure light source, and the parylene-functionalized polymer can be used as a negative photoresist for use in biological interface engineering. Hence, acetone, which is used during the patterning and coating or development, is not incompatible with the biomolecules incorporated during fabrication.

Infrared reflection absorption spectroscopy (IRRAS), scanning electronic microscopy (SEM) and imaging ellipsometry are used for characterize the parylene-functionalized polymer of the present invention. According to one embodiment, it is shown in an IRRAS spectrum that the unexposed portion of the photoresist layer is completely removed by the acetone solvent.

Moreover, the CVD process is a technology which deposits a reactant on a substrate in a reaction chamber to form a film, by utilizing chemical reactions and/or chemical degradations. Monomers of p-xylene and derivatives thereof lyse during the CVD process to form free radicals, and then deposit on the surface of a substrate. As the surfaces of many substrates do not have functional groups, for the purpose of bounding of biomolecules, the present invention uses p-xylene dimers having functional groups like alkynyl groups, aldehyde groups, amino groups and the like to immobilize biomolecules to the substrate surface by covalent bonds. Therefore, the photoresist energy and other functionalized p-xylene dimers (including aldehyde-, ethyne- and amino-functionalized parylene) used in the method for forming a photoresist structure of the present invention allow for seamless covalent bonding to construct a unique surface microstructure.

According to an embodiment, when conducting the method for forming a photoresist structure, prior to the step of forming a photoresist layer on a substrate, the photoresist layer and the substrate form the first polymer layer, so as to remove a portion of the area of the unexposed photoresist layer to expose the first polymer layer.

According to another embodiment, when conducting the method for forming a photoresist structure, after the step of forming a photoresist layer on a substrate, the method further includes the step of forming a second polymer layer on the photoresist layer, or alternatively, in an embodiment having the first polymer layer, the second polymer layer is formed on the photoresist layer, so as to interpose the photoresist layer between the first polymer layer and the second polymer layer.

In the above examples, the first polymer layer and the second polymer layer are each formed by chemical vapor deposition. It should be noted that, the first polymer layer and the second polymer layer refer to any one of the first polymer layer, the second polymer layer and the third polymer layer hereinafter.

According to one embodiment, after the first polymer layer and the photoresist layer are deposited sequentially on substrate, UV rays are used for exposure. Then, deposition takes place to form the second polymer layer. Then, acetone is used to wash away an unexposed photoresist layer and a portion of the area of the second photoresist layer, so as to keep the first polymer layer, the photoresist layer and the second polymer layer with even thicknesses.

According to the present invention, when using chemical vapor deposition to deposit a parylene-functionalized polymer of the present invention on a substrate, solvents, initiators or other additional additives are not needed. Further, the thickness of the produced photoresist can be controlled and the thickness of the photoresist is even, such that the method of the present invention can be extended to applications in other devices having complex geometries and three-dimensional structures. As such, disadvantages like uneven thicknesses generated by using a conventional spin-coating approach and limitations to coating on two-dimensional devices or substrates can be eliminated.

Furthermore, the parylene-functionalized polymer of the present invention does not have potential toxicity to biological environments. Also, development approach does not destroy the biomolecules. The parylene-functionalized polymer can be employed with other p-xylene to prepare surface microstructures with precise control with respect to spatial spectra and chemical properties. Moreover, the method of the present invention can be used to construct multifunctional surface spectral structures, and to immobilize various unique biomolecules by effect bounding via covalent bonds to achieve the technology of multifunctional biomimicry.

### EXAMPLES

In the following, specific embodiments are provided to illustrate the detailed description of the present invention, but the examples should not limit the scope of the present invention. Those skilled in the art can easily conceive the other advantages and effects of the present invention, based on the disclosure of the specification. The present invention can also be practiced or applied by referring to the other different embodiments. Each of the details in the specification can also be modified or altered in various ways in view of different aspects and applications, without departing from the spirit of the disclosure of the present invention.

The terms “two-dimensional (2D)” or “three-dimensional (3D)” used in the present invention refers to the definition of a substrate by dimensions like height, width and length and/or shape. In addition, the dimensions (i.e., two-dimensional or three-dimensional) used herein are usually measured in micrometers (μm) and nanometers (nm).

Moreover, the terms “first,” “second” and “third” used in the present invention are only used to cope with the disclosure of the specification, for a person skilled in the art to conceive and peruse, and do not have substantive technical meanings. Thus, the terms are not for limiting the order for forming the polymer layers of the present invention.

Commercially available parylene coatings are usually referred to as non-reactive parylenes, including parylene-N, parylene-C, parylene-D and parylene-F, have been used over 20 years as coatings for various medical and electronic devices, because of their biocompatible/biostable properties of moisture, chemical and dielectric barrier protection. The coatings can be prepared on devices with complex geometries in high fidelity at room temperature or below; which is favorable for most biological applications.

In addition, the use of parylene for several medical implants (for example, drug-eluting stent, blood bags and defibrillators) has gained approval by administrative agencies (e.g., the U.S. Food and Drug Administration (FDA)).

The parylene-functionalized polymers used in the examples are shown below in Table 1.

TABLE 1

| | | | Groups |
|---|---|---|---|
| | Chemical | Functional | bioconjugated |
| | structures | groups | with a reagent |
| Photoresist 1 | 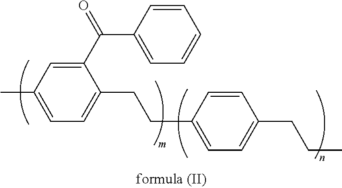 | Benzoyl group | — |
| Polymer 2 | 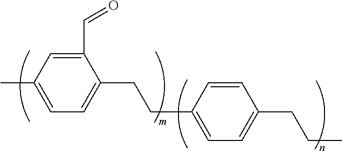 | Aldehyde group | Hydrazide |
| Polymer 3 | 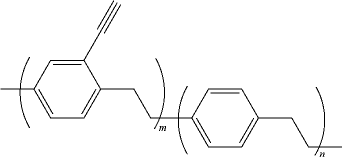 | Ethynyl group | Azide |
| Polymer 4 | 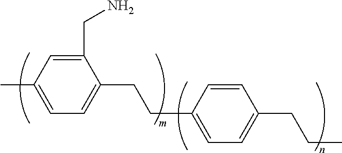 | Amino group | NHS ester |

In Table 1, m:n is 1:1.

### Materials

Unless otherwise noted, the following materials were obtained commercially and used as received: [2,2]-paracyclophane (purchased from Jiangsu Miaoquiao Synthesis Chemical Co., Ltd., 98%), aluminum chloride (purchased from Alfa Aesar), benzyl chloride (purchased from Alfa Aesar, 99%), dichloromethane (purchased from Macron Chemicals), titanium (VI) chloride (purchased from Fluka, 99%), anhydrous MgSO₄ (purchased from J. T. Baker, 99.5%), ammonium chloride (purchased from J.T. Baker, 99.5%), bromomethyl triphenylphosphonium bromide (purchased from Acros, 98%), potassium tert-butoxide (purchased from Acros, 98%), sodium (purchased from Nihon Seiyaku Kogyo Co., Ltd., 99.9%), THF (purchased from Mallinckrodt), acetone (purchased from Macron Chemicals), diethyl ether (purchased from Macron Chemicals), dichloromethyl methyl ether (purchased from TGI, 97%), and hexane (purchased from Macron Chemicals).

Gold substrates were fabricated using a 4 in. silicon wafer with a titanium layer of 300 Å, followed by a gold layer of 700 Å using a thermal evaporator (purchased from Kao Duen Technology Co., Taiwan). All of the silicon substrates were cleaned by using a piranha solution (3:1 ratio of H₂SO₄ and H₂O₂) before use.

The present invention uses two different types of stents as the non-conventional substrates for CVD coating. The first type is a self-expanding stent (Abbott, RX Acculink Carotid Stent System) that has the dimension of a 7 mm internal diameter on one end and a 5 mm internal diameter on the other end, and a length of 40 mm, was cleaned by using ethanol before CVD deposition. The second type is a balloon-expanding stent (Medtronic, Driver, Co—Cr), that has a diameter of 3.5 mm and a length of 18 mm, was also cleaned by using ethanol before CVD coating.

### CVD Polymerization

By using CVD polymerization, 4-formyl[2,2]paracyclophane, 4-benzoyl [2,2]paracyclophane, 4-ethynyl[2,2]paracyclophane or 4-aminomethyl [2,2]paracyclophane were used, respectively, as starting materials (50 mg each). First, the starting material sublimated in a vacuum in the sublimation zone at a temperature of (about 90 to 125° C.). The sublimated species where then transferred in a stream of argon carrier gas (30 sccm) to the pyrolysis zone at 670 to 800° C. Following pyrolysis, diradicals having benzoyl groups (i.e., intermediates) are generated. Finally, the photoresist 1 and the polymers 2 to 4, as shown in Table 1, are generated. During the entire CVD polymerization, a pressure of 75 mTorr was regulated, and all of the deposition rates were maintained at approximately 0.5 A/s.

### Photochemical Reaction and Development

A photomask containing of 50 μm×50 μm and 400 μm×400 μm square arrays were designed using AutoCad, and were printed on high-resolution emulsion transparency (TKK, Taiwan) with 10,000 dpi spatial resolution. After uniform deposition of poly(4-benzoyl-p-xylylene-co-p-xylylene) (hereinafter referred to as the photoresist 1), the samples were exposed to exposed to a box-type UV light source (approximately 365 nm, max: 65 mW cm⁻², Univex, Taiwan) by CVD polymerization for 15 min, while the photomask was used during the exposure to guide the photochemical reactions. Development was conducted by immersing the samples in an agitated acetone bath for 10 minutes, to remove the non-crosslinked photoresist 1.

The photopatterning process on photoresist-coated stent substrates was performed by using a Nikon TE-2000U microscope with a 10×N.A. 0.3 lens. A high-resolution emulsion photomask with a predefined pattern was placed on the field-stop plane of the microscope for projection photolithography. A 100 W HBO mercury lamp was used to serve as the UV light source to initiate the reaction. The exposure time was from 10 to 50 seconds, as controlled by a VS25 shutter system (Uniblitz) and driven by a VMM-T1 shutter driver. The resulting stent substrates were developed by using acetone and by following the same development procedures.

### Surface Characterizations

Film thickness analysis was recorded using single-wavelength (532 nm) EP³-SW imaging ellipsometry (Nanofilm Technologie GmbH, Germany). The nulling (four zones) and mapping experiments were both performed at an incident angle of 50°, and a constant n (refractive index) and k (extinction coefficient) value model was used to model the ellipsometric parameters, T(psi) and A(delta).

For the mapping mode, measurements were performed by using an imaging scanner with a lateral resolution of 1 μm at a field view of approximately 400 μm×400 μm. The images were captured by using a CCD camera with a maximum resolution of 768×572 pixels.

For film thicknesses greater than 200 nm, the analysis was performed by using a stylus-based surface profiler (Veeco, Dektak 6M).

IR spectroscopy was performed on a Thermo/Nicolet Nexus 470 spectrometer with liquid nitrogen cooled MCT detector.

A scanning electron microscope (PEI, Nova NanoSEM 230) was used to verify the uniformity of the microstructured substrate surface, and was operated at a primary energy of 5 k eV with a pressure of 5×10⁻⁶ Torr in the specimen chamber.

### Bioconjugation Reactions

To demonstrate that multiple biomolecules can be introduced to the surface of the microstructures and have the capability to accommodate multiple biomolecules, various unique bioconjugation technologies are used, to achieve controlling of the bonding of biomolecules, and to verify the reactivity of the functional groups on the microstructures after development hereinafter. Alexa Fluor 350-conjugated hydrazide (Molecular Probes) and Alexa Fluor 555-conjugated azide (Molecular Probes) were used to visualize the resulting patterns on the surface.

The hydrazide solution, prepared at a concentration of 250 μg/mL in a phosphate-buffered solution (PBS, pH 7.4) (Sigma Aldrich), was dispensed onto the structured surface in an acidic solution. After 10 minutes of reaction, the excess and unreacted hydrazide solution was rinsed off by using PBS (containing 0.1% (wt/vol) bovine serum albumin, 0.02% (v/v) Tween) and deionized water. The click reaction on the same sample was performed by reacting 150 μg/mL of Alexa Fluor 555-conjugated azide solution to the polymer 3, in the presence of a Cu⁺ catalyst in an aqueous solution for 2 hours. Finally, the sample was rinsed several times with the PBS solution (containing 0.1% (wt/vol) bovine serum albumin, 0.02% (v/v) Tween 20) and deionized water, and was then gently dried in a nitrogen stream.

For the conjugation reactions on stent substrates, 150 μg/mL of Atto-655-NHS ester (Sigma Aldrich) in PBS (containing 0.1% (wt/vol) bovine serum albumin, 0.02% (v/v) Tween 20) was first incubated with the microstructured stent for 120 minutes. After rinsing with the PBS solution (containing 0.1% (wt/vol) bovine serum albumin, 0.02 wt % (v/v) Tween 20) and deionized water, the resulting stent sample was then incubated with biotin-hydrazide (1 mg/mL, Thermo Scientific/Pierce) in PBS for 10 minutes. After rinsing with PBS, the sample was incubated with fluorescein (FITC)-conjugated streptavidin (20 μg/mL, Thermo Scientific/Pierce) in PBS (containing 0.1% (wt/vol) bovine serum albumin, 0.02% (v/v) Tween 20) for 60 minutes. Finally, the stent sample was rinsed several times with PBS (containing 0.1% (wt/vol) bovine serum albumin, 0.02% (v/v) Tween 20) and deionized water, and a nitrogen stream was used gently to dry the stent sample. Fluorescence images were captured using a Nikon TE-2000U fluorescence microscope.

### Example 1

### Use of Infrared Reflection Absorption Spectroscopy (IRRAS) to Analyze the Photoresist Layer Deposited using the Photoresist 1

The following chemical vapor deposition (CVD) polymerization uses [2,2]parachlophane having a benzoyl group as a starting material (about 5 mg). First, sublimation took place at a sublimation zone (at about 90 to 125° C.) in vacuum. Then, argon carrier gas (30 sccm) was delivered to a thermal decomposition zone at 670 to 800° C. As pyrolysis took place, biradicals having benzoyl groups (i.e., intermediates) were generated, and then the argon carrier gas continued to transfer the biradicals to a deposition chamber, where a photoresist layer coating film of a polymer (i.e., the photoresist 1) having a structure represented by formula (II) was then generated. The substrate used for deposition can be chosen by the user. In this example, the substrate selected can be silicon and silicon coated with gold. During the entire CVD polymerization, the temperature was regulated to 7 mTorr, and the deposition rate was kept at about 0.5 Angstrom/second.

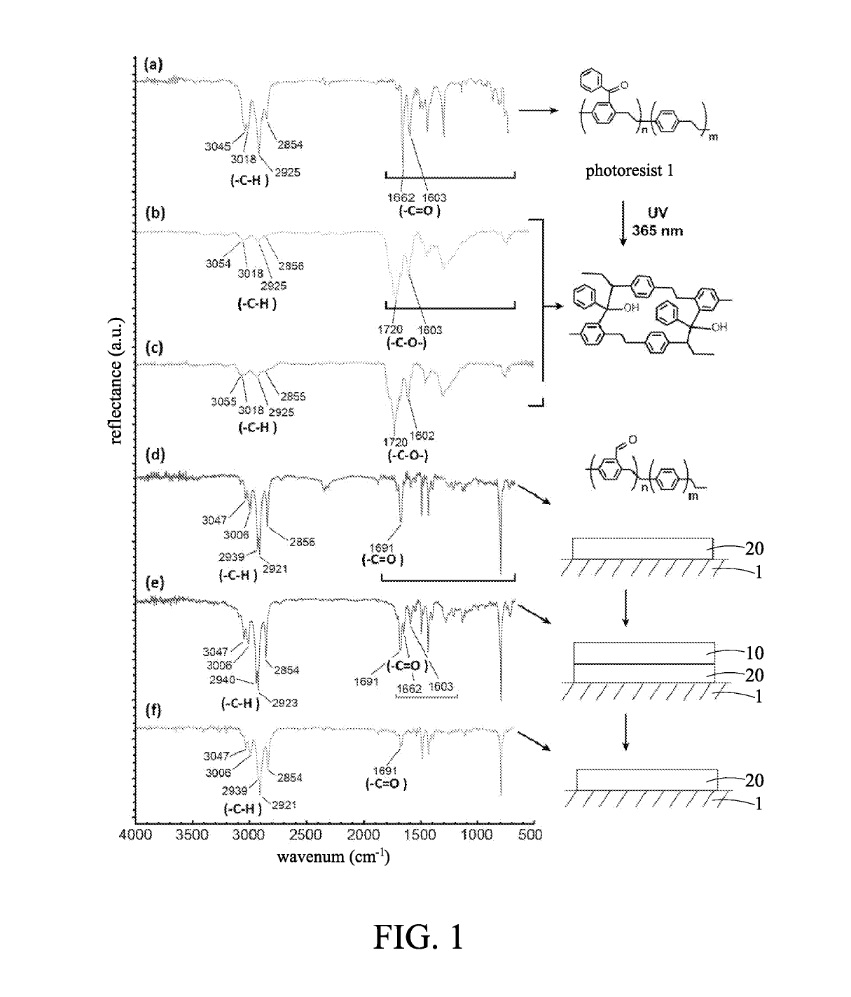

Referring to FIG. 1(a), the photoresist layer formed by depositing the photoresist 1 was analyzed by using IRRAS. The results were that there were characteristic bands of carbonyl stretch at 1603 cm⁻¹ and 1662 cm⁻¹.

Then, a box-type UV light source (maximum 65 mWatts/square centimeters, Univex) at about 365 nm was used to expose the photoresist layer, and an IRRAS analysis was similarly performed. As shown in FIG. 1(b), a decreased 1662 cm⁻¹ band and a strong absorption of —C—O— stretch in 1720 cm⁻¹ were detected, indicating that the photoresist 1 has intersystem crossing and acyl group was converted to —CO carrying a free electronic group.

Finally, development was conducted on the exposed photoresist layer by using acetone. The process was to impregnate the sample in an agitated acetone bath for 10 minutes to remove the non-crosslinked photoresist 1, so as to obtain the desired development and surface structure In a further verification through an IRRAS cross-analysis, it was found that the exposed photoresist significantly increased the overall stability of the photoresist layer due to the cross-linking reaction between the molecular structures. Thus, the exposed photoresist was not affected by development with an acetone solution (as compared with the unexposed photoresist layer, the non-crosslinked structure was removed by acetone solution during development). As shown in FIG. 1(c), for the exposed photoresist layer, characteristic bands at 1602 cm⁻¹ and 1720 cm⁻¹ can be detected. The detection results match FIG. 1(b) (i.e., the photoresist layer was exposed, but not yet developed). This also verified that, after the photoresist layer was exposed to UV irradiation at 365 nm, the stable cross-linking structures of the photoresist layer will not be affected by acetone development.

### Example 2

### Use of IRRAS to Analyze the First Polymer Layer 20 and the Photoresist Layer 10 Deposited by using the Polymer 2 and the Photoresist 1, Respectively

Please refer to FIGS. 1(d) and 1(f), poly(4-formyl-p-xylylene-co-p-xylylene), which is referred to as the polymer 2 hereinafter, was deposited on the silicon and the silicon substrate coated with gold, to form the first polymer layer 20 (referring to FIG. 1(d)), by the same CVD process as in example 1. Then, the photoresist 1 was deposited to form a photoresist layer 10 (referring to FIG. 1(e)).

Then, acetone washing process proceeded, which involved the impregnation of the sample in an agitated acetone bath for 10 minutes to remove the non-crosslinked photoresist 1, so as to remove the photoresist layer 10 completely, while the first polymer layer 20 was completely retained on the substrate 1.

As shown FIG. 1(d), results from an IRRAS analysis indicated that a band at 1691 cm⁻¹ was detected after depositing the first polymer layer 20 with the polymer 2. Afterwards, as shown in FIG. 1(e), after depositing the photoresist layer 10 on the first polymer layer 20, there was a sign of superimposition of a band at 1691 cm⁻¹ from the first polymer layer 10 formed from the polymer 2 and the bands at 1662 and 1603 cm⁻¹ from the photoresist layer 10 formed from the photoresist 1. As shown in FIG. 1(f), since the photoresist layer 10 was completely removed, there was no detection of traces of characteristic peaks from the photoresist 10, and only a band at 1691 cm⁻¹ from the first polymer layer 20 was detected. This proves the feasibility of using acetone as a developing solution. Thus, the present invention uses acetone in development to remove unexposed photoresist layers.

### Example 3

### Use of a Scanning Electron Microscope (SEM) and Imaging Ellipsometry for Detecting and Analyzing a Photoresist Layer Deposited with the Photoresist 1

By using the same CVD process as in examples 1 and 2, the photoresist 1 was deposited on the silicon substrate to form a photoresist layer. Then, a box-type UV light source (maximum 65 mWatts/square meters, Univex) at 365 nm was used to expose a portion of an area of the photoresist layer for 5 minutes, while a photomask with a 50 μm×50 μm square array was used to induce a photochemical reaction. Finally, after development was conducted to remove an unexposed photoresist layer in an agitated acetone bath, SEM and imaging ellipsometry were used in combination to analyze the microstructure of the photoresist layer.

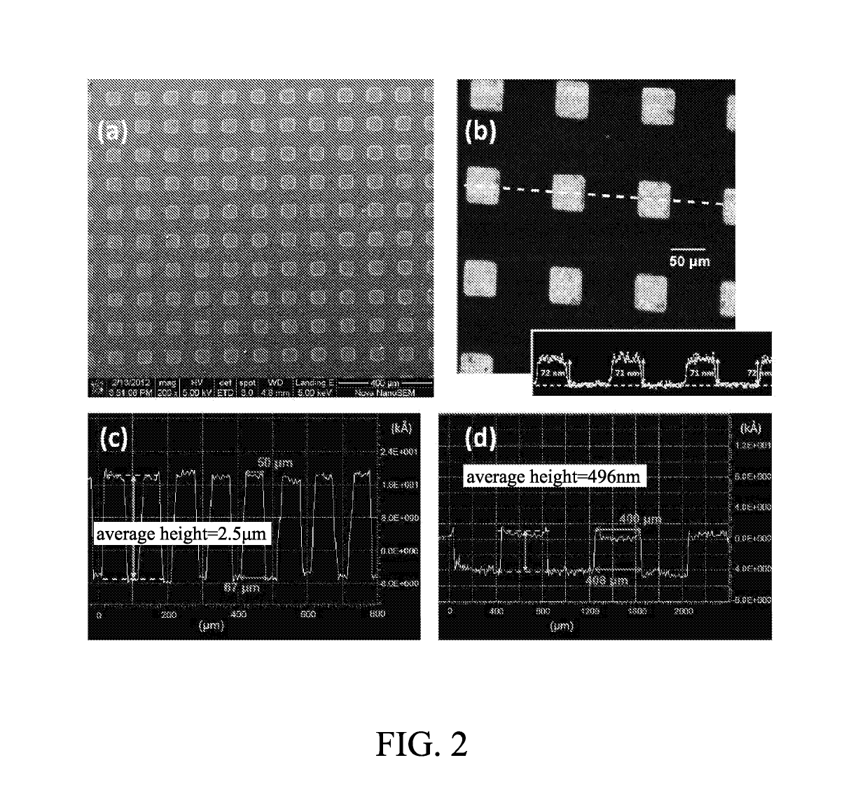

Please refer to FIG. 2(a), the SEM image shows that the shape of each individual unit in the large surface area (1.5 mm×1 5 mm) was not damaged, indicating that the microstructure formed by the exposed photoresist layer remain intact after the photoresist layer was washed with acetone.

As shown in FIG. 2(b), in the data obtained from an imagining ellipsometry thickness map, the thickness distribution of the 50 μm×50 μm square array over the 400 μm×400 μm area can be obviously detected, and be further analyzed for thickness. The histogram in the bottom right corner indicates the thickness distribution curve of the cross-section along white dash lines. The histogram shows that a thickness of from 71 nm to 72 nm was formed. FIG. 2(b) shows that the pattern fidelity of the exposed photoresist layer is not damaged during the development stage. In addition, the overall thickness of the photoresist layer is about 70 nm, and the root-mean-square (rms) roughness shows that the average value of the photoresist layer was about 1.3 nm The average value of the microstructure surface after development with acetone was 1.5 nm, indicating that the interference of surface roughness caused by development was negligible.

In the example, ellipsometry was similarly used to analyze other ranges of thicknesses. As shown in FIGS. 2(c) and 2(d), the thicknesses were 2.5 μm of 50 μm×50 μm square array of the photoresist layer and 496 nm of 400 μm×400 μm square array of the photoresist layer. By analyzing the result data, it shows that the average thickness of the sidewall profile of the patterns was detected to be 2.5 μm thick, the base of the structure was detected to have a width of 67 μm, while a width of 50 μm was found on the top opposite side. This is not far from the predetermined size of 50 μm, and the error is within a reasonable range. FIG. 2(d) shows the detection of a structure having an average height of 496 nm, wherein a structure in which the base of the substrate had a width of 408 μm and the opposite side had a width of 400 μm were found. This is not far from the predetermined size of 400 μm, and the error is within a reasonable range.

### Example 4

### Immobilization of Multiple Biomolecules on a Substrate Surface

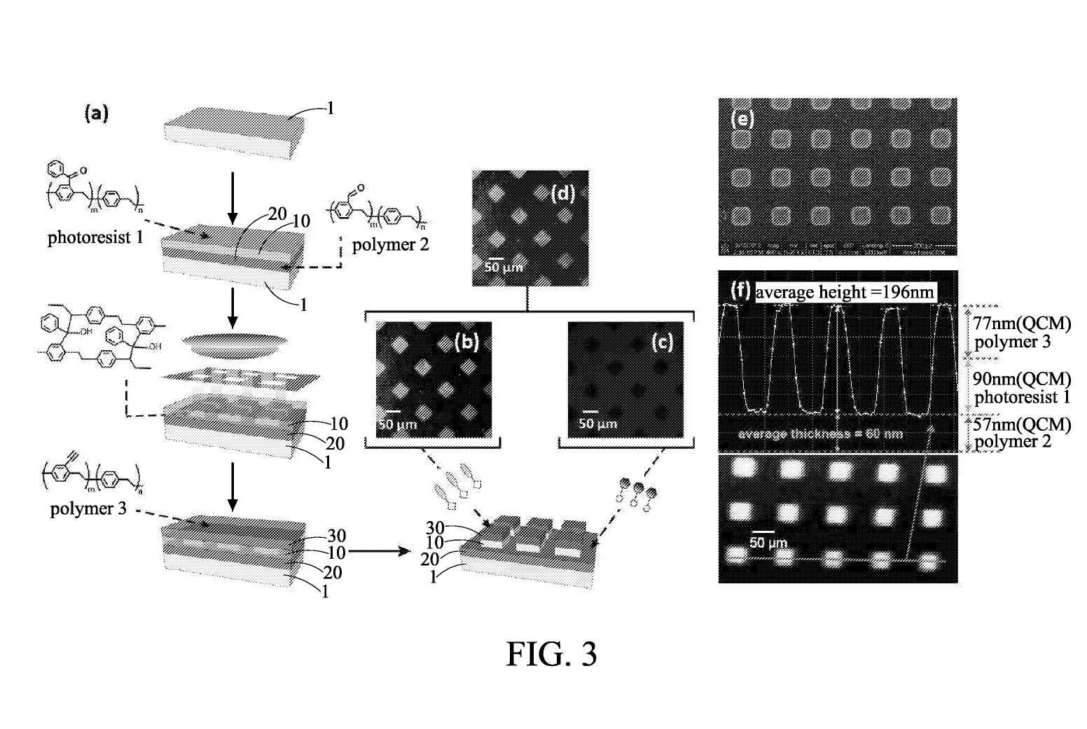

Below, a microstructure of a specific reactive operation for use in the immobilization of biomolecules is produced. Please refer to FIG. 3(a), in the same CVD process as in examples 1 and 2, the flat substrate 1 (i.e., silicon and silicon coated with gold) was provided, and the polymer 2 was deposited on the substrate 1 as a base to form the first polymer layer 20. Then, the photoresist 1 acted as an intermediate layer to deposit the photoresist layer 10 on the first polymer layer 20. After the photoresist layer 10 was subjected to UV irradiation with a photomask of 50 μm×50 μm square array, Alexa Fluor-350 hydrazide molecules were reacted with the aldehyde groups on the microarray structure of the polymer 2 produced after exposure on the substrate 1 (by click reaction). Then, poly(4-ethynyl-p-xylylene-co-p-xylylene), which is referred to the polymer 3 hereinafter, served as a top layer to be deposited on the photoresist layer 10 to form the second polymer layer 30. Alexa Fluor-555 azide was clicked to the ethynyl groups of the polymer 3 to perform the click reaction. Afterwards, acetone washing was conducted to completely remove the non-crosslinked photoresist layer 10 and the second polymer layer 30.

FIGS. 3(b) to 3(c) are fluorescent micrographs, wherein FIG. 3(b) shows that the ethynyl groups on the surface of the second polymer layer 30 can be conjugated to immobilize an Alexa Fluor-555 azide by using Huisgen 1,3-dipolar cycloaddition (which is a type of click addition), FIG. 3(c) shows that Alexa Fluor-350 hydrazide can also form chemical bond of hydrazones with the aldehyde groups on the first polymer layer 20 via another conjugation, and FIG. 3(d), which is a superimposed image of FIGS. 3(b) and 3(c), shows that the levels of precision of the conjugation and immobilization all occur at the estimated positions. The area where the fluorescent signal was detected matched with the microstructure produced, and no cross-reaction occurred. Therefore, the first polymer layer 20 and the second polymer layer 30 formed by depositing the polymer 2 and the polymer 3, respectively, were stable during acetone development, and the reactivity thereof was retained. Further, these results also show that the unexposed photoresist layer 10 can be completely removed with acetone, to expose the first polymer layer 20 from the base.

FIG. 3(e) is an SEM image, which shows the uniformity of the laminate structure prior to immobilization of the biomolecules, i.e., the microstructure composed by the laminated first polymer layer 20, the photoresist layer 10 and the second polymer layer 30 were uniformly produced.

FIG. 3(f) represent an imaging ellipsometry thickness map (bottom image) and thickness profile (top image), which were recorded on the layered structure prior to immobilization. The results show that the average thickness of the first polymer layer 20 was 57 nm, the thickness of the photoresist layer 10 was 90 nm, and the thickness of the second polymer layer 30 was 77 nm The results were the same as those of the monitored QCM thickness analysis during CVD polymerization.

### Example 5

### Formation of a Photoresist Layer on a Stent

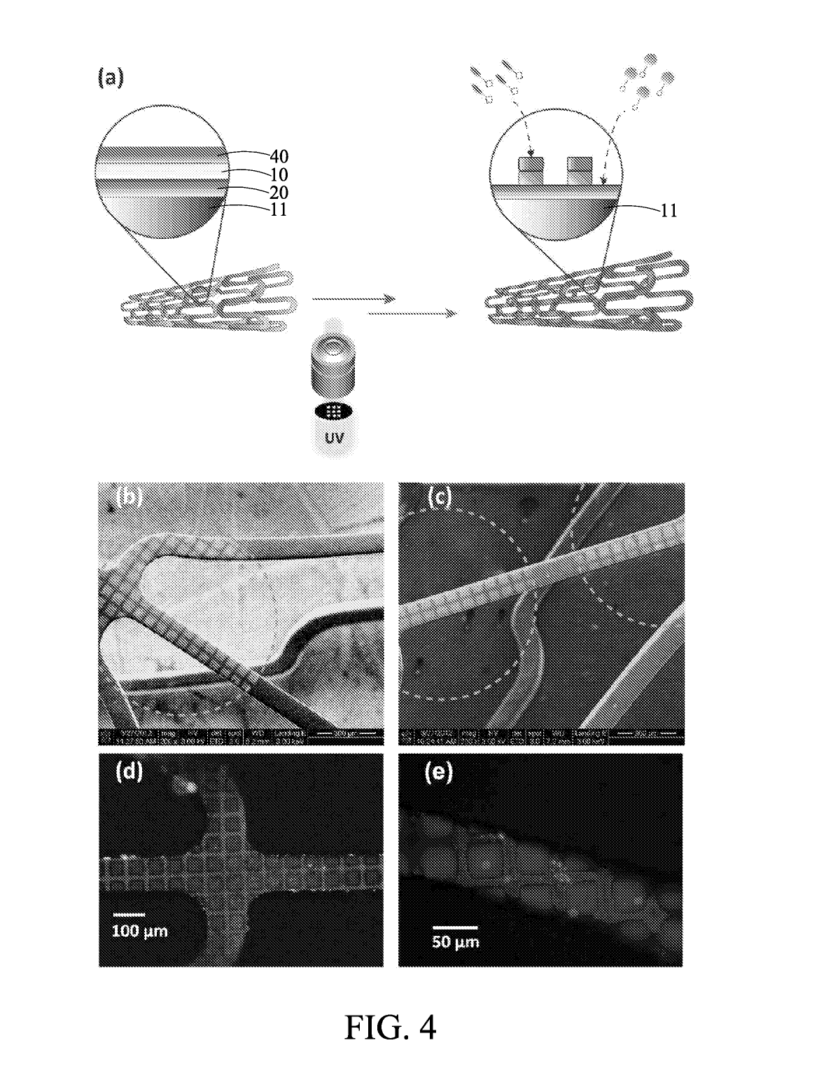

Please refer to FIG. 4(a), the followings are sequentially formed on an expanded stent substrate 11: the first polymer layer 20 having aldehyde groups formed by depositing the polymer 2, depositing the photoresist 1 to form the photoresist layer 10, and depositing poly(4-aminomethyl-p-xylylene-co-p-xylylene), which is referred to the polymer 4 hereinafter, on the top to form the third polymer layer 40.

Because the surface of the stent substrate 11 has a complex geometry, the use of a Nikon TE-2000U microscope having a 10× NA 0.3 lens to perform a microscopic patterning technique to replace a transparent photomask and to perform photoillumination on the stent surface. After the irradiation, acetone was similarly used to perform development. Because the stent surface has a functional microarray structure after development, its functionality includes aldehyde groups from the first polymer layer 20 and amino groups from the third polymer layer 40. Different specific conjugations were further used to immobilize the multiple biomolecules on a microarray structure on the stent. In the example, the surface of the polymer 4 can immobilize biotin hydrazide molecules in a specific zone through a specific conjugation between the hydrazides and the aldehyde groups. Then, a linkage was spontaneously formed with an FITC-streptavidin, which had a high affinity to biotins by a linking reaction. On the other hand, a succinimide-amine conjugation chemical method was used, which utilized fluorescence-containing Atto-655-NHS ester molecules to detect the amino groups of the third polymer layer 40.

An SEM observation of the architecture of the stent surface after development is provided. The results are shown in FIGS. 4(b) and 4(c), wherein FIG. 4(b) is an SEM micrograph showing the complex joint area of the stent after a one-time projection on the stent, and FIG. 4(c) is an SEM micrograph showing the string area of the stent after two consecutive projections. The dash lines represent the perimeters of the projected areas.

FIGS. 4(d) and 4(e) show superimposed fluorescent micrographs in the joint area (from the self-expanded stent) and the string area (from the balloon expanded stent). It is shown that, after specific conjugations, Atto-655 ester molecules (red) were bonded to the third polymer layer 40 formed by the amine-containing polymer 4, and the biotin-hydrazides and the FITC-steptavidin (green) after the spontaneous linkage were immobilized on the first polymer layer 20 formed by the aldehyde-containing polymer 2. In addition, the portions where the images are blurred in FIGS. 4(d) and 4(e) were caused by depth of focus.

In light of the results shown above, the method for forming a photoresist structure of the present invention can extend the application of a photoresist to other devices with complex geometries or three-dimensional devices. Further, the photoresist can be used in combination with other parylene molecules to prepare a precisely controlled surface microstructure with respect to the spatial spectra and the chemical properties.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A method for forming a photoresist structure, comprising the following steps of:
forming a photoresist layer above a substrate;
exposing a portion of the photoresist layer to form an exposed portion of the photoresist layer; and
removing the photoresist layer except the exposed portion with a solvent, so as to form the photoresist structure,
wherein the photoresist layer is comprised of a polymer having a structure represented by formula (I): 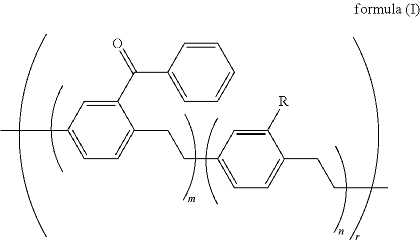
wherein R is benzoyl or a hydrogen atom;
m and n are each independently an integer in a range from 1 to 150; and
r is an integer in a range from 1 to 20000.

2. The method of claim 1, wherein R is a hydrogen atom and r is 1, and the structure of the polymer is represented by formula (II): 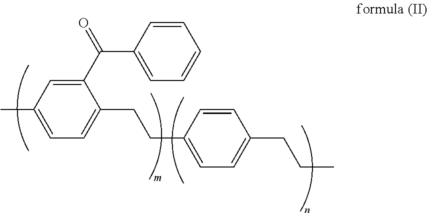
wherein m:n is 1:1.

3. The method of claim 1, wherein the photoresist layer has a thickness in a range from 70 nm to 2.5 μm.

4. The method of claim 1, wherein the photoresist layer is formed by chemical vapor deposition.

5. The method of claim 1, wherein the step of exposing is performed by using an ultraviolet light.

6. The method of claim 1, wherein the solvent is acetone.

7. The method of claim 1, further comprising the step of forming a first polymer layer on the substrate, wherein the photoresist layer is formed on the first polymer layer.

8. The method of claim 7, further comprising the step of forming a second polymer layer on the photoresist layer, so as to allow the photoresist layer to be interposed between the first polymer layer and the second polymer layer.

9. The method of claims 8, wherein the first polymer layer and the second polymer layer are each formed by chemical vapor deposition.
